(19) United States
(12) Patent Application Publication
(10) Pub. No.: US 2013/0234559 A1
(43) Pub. Date: Sep. 12, 2013

(54) PIEZOELECTRIC RESONATOR

(71) Applicant: Vladimir Ermolov, Espoo (FI)

(72) Inventor: Vladimir Ermolov, Espoo (FI)

(73) Assignee: Nokia Corporation, Espoo (FI)

(21) Appl. No.: 13/884,687

(22) PCT Filed: Nov. 25, 2010
(86) PCT No.: PCT/IB10/55417

§ 371 Date: May 10, 2013

(51) Int. Cl. H01L 41/047

(52) U.S. Cl. CPC H01L 41/047
USPC 310/321

(57) ABSTRACT

An apparatus (200) comprising: a first electrode (204), wherein the first electrode comprises at least one layer of graphene; a second electrode (208); and a layer of piezoelectric material (206) disposed between the first electrode (204) and the second electrode (208), wherein the piezoelectric material (206) is able to resonate at a resonant frequency in response to application of an oscillating electrical signal to the first or second electrode (204, 208).

### FIELD OF THE INVENTION

This invention relates to a piezoelectric resonator.

### BACKGROUND TO THE INVENTION

Many modern devices contain oscillators and filters for producing and isolating high frequency signals. These components find widespread application in devices which receive and transmit radio frequency signals. It is also well known to use quartz crystal oscillators to produce accurate clock signals.

### SUMMARY OF THE INVENTION

A first aspect of the invention provides an apparatus comprising:
a first electrode, wherein the first electrode comprises at least one layer of graphene;
a second electrode; and
a layer of piezoelectric material disposed between the first electrode and the second electrode, wherein the piezoelectric material is able to resonate at a resonant frequency in response to application of an oscillating electrical signal to the first or second electrode.

The apparatus may further be configured to change a voltage bias applied to the first electrode.

The first electrode may be comprised of a single layer of graphene or of multiple layers of graphene. In addition the second electrode may be comprised of at least one layer of graphene. The resonant frequency may be a radio frequency.

The apparatus may further comprise a radio frequency signal input and a voltage bias input.

The apparatus may be incorporated in an integrated circuit. The integrated circuit may be incorporated in a circuit board. The integrated circuit or circuit board may be incorporated in a portable device

A second aspect of the invention provides a method comprising:
providing a first electrode, wherein the first electrode comprises at least one layer of graphene;
providing a second electrode; and
providing a layer of piezoelectric material disposed between the first electrode and the second electrode, wherein the piezoelectric material is able to resonate at a resonant frequency in response to application of an oscillating electrical signal to the first or second electrode.

The method may further comprise providing means for changing a voltage bias applied to the first electrode.

A third aspect of the invention provides a method of operating a device, the method comprising:
applying an oscillating electrical signal to apparatus comprising a first electrode, the first electrode comprising at least one layer of graphene, a second electrode, and a layer of piezoelectric material disposed between the first electrode and the second electrode, such as to cause the piezoelectric material to resonate at a resonant frequency; and
changing a bias voltage applied to the apparatus.

### BRIEF DESCRIPTION OF THE DRAWINGS

Embodiments of the present invention will now be described, by way of example only, with reference to the accompanying drawings, in which:

FIG. 1 is a graph showing the dependence of the capacitance of a graphene capacitor on voltage;

FIG. 2 shows a piezoelectric resonator according to exemplary embodiments of the invention;

FIG. 3 is a circuit model of the piezoelectric resonator of FIG. 2;

FIG. 4 is a circuit model showing the piezoelectric resonator of FIG. 2 in an exemplary implementation; and

FIG. 5 is a schematic illustration of an exemplary portable device containing the resonator of FIG. 2.

### DETAILED DESCRIPTION OF PREFERRED EMBODIMENTS

Graphene is a material formed of a single layer of tightly packed carbon atoms. As graphene is a planar sheet of atomic thickness, it can be considered as a two dimensional or quasi two dimensional material. Graphite and other graphitic materials are formed of many stacked layers of graphene. Although the structure of graphite has been extensively studied, the isolation of individual graphene sheets was only achieved in the last few years. Graphene sheets can be produced by the exfoliation of graphite, either mechanically or by using liquid phase solvents. Graphene can also be produced by epitaxial growth on a wide range of substrates. Early attempts at isolating graphene produced low yields of monolayer graphene, with most of the graphene produced being multilayered. More advanced techniques are being developed and it is now possible to produce graphene films which are predominantly monolayer and to produce bi-layer and tri-layer graphene sheets. Recently, very large (˜0.5 m×0.5 m), predominantly monolayer graphene films have been grown on copper substrates and transferred to flexible target substrates.

Graphene has been found to have remarkable electronic and mechanical properties, including very high electron mobility levels and very low resistivity at room temperature. If graphene is incorporated into an electrode of a capacitor, a contribution to the total capacitance can be observed due to the electronic compressibility of graphene. This contribution is often referred to as the “quantum capacitance” and is a direct measure of the density of state at the Fermi energy. An expression which is often used to define the quantum capacitance is C_{q}=e²D, where e is the electron charge and D is the density of states. The quantum capacitance is inversely proportional to the effective mass of electrons and holes in a material and so materials with a relatively high electron (and hole) mobility will have a relatively large quantum capacitance. Graphene has a Dirac-like electronic spectrum, meaning that electrons and holes have an effective mass close to zero. Because of this, the quantum capacitance of graphene is very high.

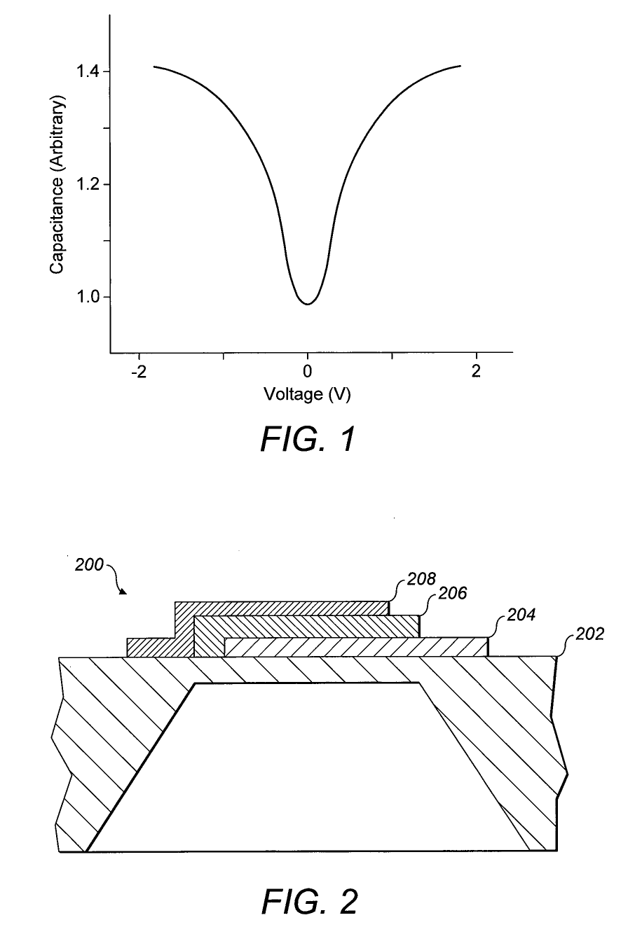

In most two dimensional systems, the quantum capacitance is usually a small, constant value. In graphene however, the density of state is a strong function of the Fermi energy. If a voltage is applied to graphene, a change in the Fermi level results, which in turn produces a change in the density of states. Referring to FIG. 1, a graph 100 is shown which illustrates the dependence of the capacitance of a graphene capacitor on the voltage difference applied across the capacitor. The axis scales are shown for illustrative purposes only. The change in total capacitance observed is due to the changing value of the quantum capacitance of the graphene. At zero applied voltage, the capacitor has a capacitance which is a product of the geometric electrostatic capacitance and the quantum capacitance. As the applied voltage is varied, the change in the quantum capacitance contribution produces pronounced changes in the total capacitance.

As described above, graphene is formally defined as a two dimensional monolayer of carbon atoms. However, in reality a manufactured sheet or film of graphene may contain regions of multilayered graphene. Imperfect graphene sheets may still exhibit the same electronic properties such as quantum capacitance required to put the claimed invention into effect. This is particularly the case with epitaxially grown graphene in which areas of multilayered graphene do not have their lattices aligned and therefore continue to behave as individual layers. As such, use of the term “graphene” is intended to encompass not only perfect monolayer graphene but also imperfect sheets of graphene having a sufficient level of electronic compressibility.

Resonators are common electrical components used in many modern devices and applications. Resonators are extensively used in radio frequency applications. Electrical resonators may take the form of an LC or RLC circuit. Alternatively, a resonator may comprise a piezoelectric material sandwiched between parallel plate electrodes. A piezoelectric material oscillates when subjected to an electric field and conversely will produce an electric field when a force is applied to it. A resonator including piezoelectric material resonates at an oscillation frequency that depends on a number of aspects of the configuration of the resonator. Crystals such as quartz are commonly used as the piezoelectric material in resonators.

Electrical tuning of the output frequency of a resonator is possible using a variable capacitor, often termed a varactor or varactor diode. A varactor usually takes the form of a reversed biased diode (possibly coupled with other circuit components) and is connected in parallel or series with the crystal electrodes. A varactor is responsive to a change in a bias voltage to cause a change in the load capacitance. A change in the load capacitance of the varactor causes a change in the resonating frequency of the piezoelectric resonator. Many voltage tunable piezoelectric resonators are “off chip” components due to the difficulty of integrating mono crystal piezoelectric materials in CMOS fabrication processes. These resonators are therefore bulky and expensive. Some techniques are being developed for integrating polycrystalline piezoelectric materials into CMOS processes allowing the fabrication of “on chip” resonators. However these resonators are expensive to produce, only polycrystalline material can be used, and the resulting resonator occupies a relatively large area of the chip.

Referring now to FIG. 2, a structural representation of a resonator 200 embodying aspects of the present invention is shown. The resonator 200 comprises a substrate 202. Formed on top of the substrate are a lower electrode 204, a piezoelectric layer 206 and an upper electrode 208. The resonator 200 may have a number of other standard component parts which are not shown for simplicity and clarity.

In some embodiments, the lower electrode 204 is formed of graphene and the upper electrode 208 is made of a metallic material. A wide range of metallic materials may be used to form the upper electrode 208. In some embodiments, the upper electrode 208 is made of Aluminium.

In some embodiments, the graphene is produced by epitaxial growth on a substrate. The substrate on which the graphene is grown may be the substrate 202, or the graphene may be transferred to the substrate 202 from a different growth substrate (not shown).

The piezoelectric layer 206 is disposed between the lower electrode 204 and the upper electrode 208, which form a parallel plate structure. When an alternating current is applied to one of the electrodes 204, 208 an alternating voltage difference across the parallel plate structure is produced and the piezoelectric layer 206 undergoes resonance. The frequency at which the piezoelectric layer 206 resonates depends on the type of piezoelectric material used. Quartz is the most commonly used piezoelectric crystal, however any other suitable substances may instead be used, for example lithium and gallium based crystals.

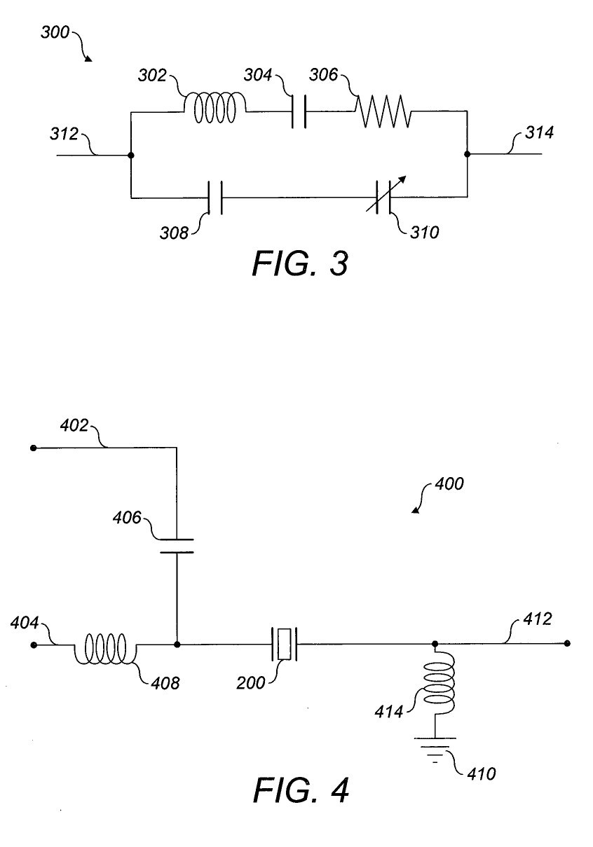

Piezoelectric resonators have a dedicated circuit symbol (see item 200 in FIG. 4). However they are often represented by an equivalent circuit so that their function may be better understood. Referring now to FIG. 3, a circuit equivalent model 300 of a piezoelectric resonator embodying some aspects of the present invention is shown. The model 300 has a series inductor 302, a series capacitor 304, a series resistor 306, a parallel capacitor 308 and a quantum capacitor 310. The model also shows an input 312 and an output 314. The series inductor 302, the series capacitor 304 and the series resistor 306 are connected in series between the input 312 and the output 314. The parallel capacitor 308 and quantum capacitor 310 are shown connected in series with each other between the input 312 and the output 314 and are connected in parallel with the three other components. The branch containing the series inductor 302, the series capacitor 304 and the series resistor 306 is called the series branch and the branch containing the parallel capacitor 308 and the quantum capacitor 310 is called the parallel branch.

The piezoelectric resonator can be modelled in this way because many piezoelectric materials have two modes of resonance; a series resonance and a parallel resonance relating to the series and parallel branches respectively. In order for this model to be valid, the series capacitor 304 must have a much smaller capacitance than the parallel capacitor 308 and the quantum capacitor 310 combined. The parallel capacitor 308 represents the geometrical electrostatic capacitance of the piezoelectric layer 206. The quantum capacitor 310 represents the quantum capacitance component due to the electronic compressibility of graphene. The quantum capacitor 310 is shown as a variable capacitor element due to the variable nature of the quantum capacitance of graphene under an external voltage bias.

The parallel resonant frequency of the piezoelectric resonator 200 exemplified by FIGS. 2 and 3 can be tuned by changing the value of the capacitance of the system. This is achieved by changing a voltage bias applied to the electrodes of the resonator 200 when operating the resonator 200 at parallel resonance. The piezoelectric resonator 200 has a parallel plate structure as described above with reference to FIG. 2. This results in the resonator 200 having an intrinsic load capacitance. However, because one of the electrodes of the resonator 200 is made of graphene, there is a significant contribution to the total capacitance from the quantum capacitance of the graphene such that varying this contribution has a significant effect on the total capacitance.

An advantage of the resonator 200 exemplified by FIGS. 2 and 3 is that the function of tunability is built into the resonator itself. The resonator 200 is intrinsically tunable due to the property of quantum capacitance exhibited by graphene. Thus a tunable resonator can be manufactured which occupies a very small area of a chip, and can be said to be highly integratable. Experiments indicate that the resonator 200 has a pulling range and tuning voltage range similar to that of current varactor-coupled tunable resonators, even at normal operating temperatures. These experiments also indicate that the resonator 200 has a comparable level of integration to resonators where a physical constant of the piezoelectric layer is controlled by the application of a voltage, although the pulling range and tuning voltage range of the resonator 200 is far superior.

FIG. 4 shows an exemplary circuit 400 embodying some aspects of the present invention. The circuit 400 of FIG. 4 has a first input 402, a second input 404 and an output 412. Both the first and second inputs 402, 404 are coupled to a first electrode of the piezoelectric resonator 200. The output 412 is coupled to the second electrode of the piezoelectric resonator 200. A capacitor 406 is located on the first input 402. An inductor 408 is located on the second input 404. A connection to ground 410 is coupled to the output 412. A grounded inductor 414 is located between the output 412 and the connection to ground 410.

The piezoelectric resonator 200 requires an oscillating input signal in order for the piezoelectric layer 206 to resonate. An oscillating signal is applied via the first input 402. This signal may be generated in any suitable way, for example by a signal generator. The oscillating signal is preferably a radio frequency signal of approximately the same frequency as the resonating frequency of the piezoelectric layer 206. The capacitor 406 acts as a low frequency block. This results in a cleaner oscillating signal reaching the resonator 200. The capacitor 406 could instead be replaced or augmented by a more complex high-pass filter arrangement.

A direct current (DC) signal or low frequency alternating current (AC) signal is applied via the second input 404. The inductor 408 acts as a high frequency choke. This ensures that the oscillating signal applied to the first input 402 is not passed to components attached to the second input 404. The inductor 408 could instead be replaced or augmented by a more complex low pass filter arrangement. The voltage bias used to control the quantum capacitance of the graphene electrode is received at the second input 404 signal.

When the oscillating signal and the DC or low frequency AC signal are applied to the resonator 200 via the first and second inputs 402 and 404 respectively, the piezoelectric layer 206 is caused to resonate. The resonant frequency, which is the frequency at which the piezoelectric layer 206 oscillates, is dependent on the load capacitance of the resonator 200. If the load capacitance is increased, the resonant frequency is pulled downwards. If the load capacitance is decreased, the resonant frequency is pulled upwards. The resonator 200 therefore produces an oscillating signal which is output through the output 412. The grounded inductor 414 and connection to ground 410 provides grounding for low frequency or DC signals. The grounded inductor 414 acts as a radio frequency choke, ensuring that the radio frequency signals are output through the output 412.

The circuit 400 may also include control electronics (not shown) for receiving instruction to alter the output signal frequency and controlling the voltage bias applied to the resonator 200.

The piezoelectric resonator 200 could be considered to operate like a high quality filter. An oscillating signal having a relatively high bandwidth (low Q factor) is input via the first input 402. The piezoelectric layer 206 resonates with a high Q factor, producing an output signal with a much lower bandwidth. In addition, this high quality output signal is tunable as described above. In some embodiments (not shown), two or more resonators may be used in combination.

In some embodiments, both the lower and upper electrodes 204, 208 of the piezoelectric resonator 200 are made of graphene. This may increase the amount by which the quantum capacitance changes in response to a change in the applied voltage bias and therefore the range over which the resonating frequency can be pulled. In some embodiments, the graphene electrodes may be made of multilayer graphene having, for example, two or three layers of graphene. Such multilayered graphene has some different electronic properties such as an increased conductivity; however it retains many of its original properties. Due to current epitaxial graphene growth techniques, the hexagonal lattices of upper and lower layers are randomly orientated, allowing the layers to behave independently.

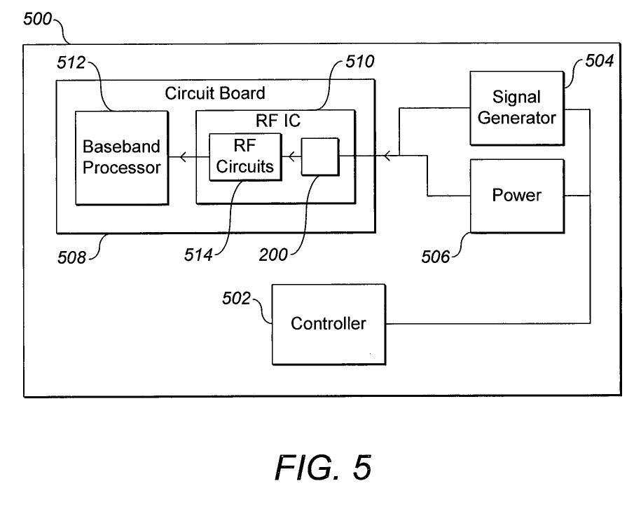

FIG. 5 shows a schematic of an exemplary portable device 500 in which the resonator 200 is utilised. The portable device 500 comprises a controller 502, a signal generator 504 and a power generator 506. The controller 502 is connected to the signal generator 504 and the power generator 506 in order to control the outputs thereof. The portable device 500 also comprises a circuit board 508. The circuit board 508 has disposed thereon a radio frequency integrated circuit 510 and a baseband processor 512. Located on the radio frequency integrated circuit 510 are the piezoelectric resonator 200 and radio frequency circuits 514. The portable device 500 may contain many other components which are not shown for reasons of clarity.

The piezoelectric resonator 200 is configured to produce a radio frequency output signal as described above. This signal is passed to other components on the radio frequency integrated circuit 510, represented by radio frequency circuits 514. The radio frequency circuits 514 uses the signal created by the resonator 200 to produce baseband signals, which are passed to the baseband processor 512. The radio frequency circuits 514 may be any combination of suitable components configured to perform a variety of tasks.

An oscillating electrical signal input is applied by the signal generator 504 to the resonator 200. A DC or low frequency AC voltage bias is applied by the power generator 506 to the resonator 200. The controller 502 is configured to control the power generator 506 to change the applied bias voltage. The controller 502 may also be configured to control the signal generator 504 to change the frequency of the applied oscillating signal. The portable device 500 may have some feedback means (not shown) so that the controller 502 may monitor the voltage bias and oscillating signal being applied to the resonator 200 and to monitor the output from the resonator 200.

Resonators 200 as described above are implemented in voltage controlled oscillators in some embodiments and in tunable filters in other embodiments.

It will be appreciated that the above described embodiments are purely illustrative and are not limiting on the scope of the invention. Other variations and modifications will be apparent to persons skilled in the art upon reading the present application. Moreover, the disclosure of the present application should be understood to include any novel features or any novel combination of features either explicitly or implicitly disclosed herein or any generalization thereof and during the prosecution of the present application or of any application derived therefrom, new claims may be formulated to cover any such features and/or combination of such features.

1-16. (canceled)

17. An apparatus comprising:
a first electrode, wherein the first electrode comprises at least one layer of graphene;
a second electrode; and
a layer of piezoelectric material disposed between the first electrode and the second electrode, wherein the piezoelectric material is able to resonate at a resonant frequency in response to application of an oscillating electrical signal to the first or second electrode.

18. An apparatus according to claim 17, wherein the apparatus is configured to change a voltage bias applied to the first electrode.

19. An apparatus according to claim 17, wherein the first electrode comprises a single layer of graphene.

20. An apparatus according to claim 17, wherein the first electrode comprises multiple layers of graphene.

21. An apparatus according to claim 17, wherein the second electrode comprises at least one layer of graphene.

22. An apparatus according claim 17, wherein the resonant frequency is a radio frequency.

23. An apparatus according to claim 17, wherein the apparatus further comprises a radio frequency signal input and a voltage bias input.

24. An integrated circuit incorporating the apparatus of claim 17.

25. A circuit board including the integrated circuit of claim 24.

26. A portable device including apparatus as claimed in claim 17, the integrated circuit of claim 24 or the circuit board of claim 25.

27. A method comprising:
providing a first electrode, wherein the first electrode comprises at least one layer of graphene;
providing a second electrode; and
providing a layer of piezoelectric material disposed between the first electrode and the second electrode, wherein the piezoelectric material is able to resonate at a resonant frequency in response to application of an oscillating electrical signal to the first or second electrode.

28. A method according to claim 27, further comprising providing means for changing a voltage bias applied to the first electrode.

29. A method according to claim 27, wherein the first electrode comprises a single layer of graphene.

30. A method according to claim 27, wherein the first electrode comprises multiple layers of graphene.

31. A method according to claim 27, wherein the second electrode comprises at least one layer of graphene.

32. A method of operating a device, the method comprising:
applying an oscillating electrical signal to apparatus comprising a first electrode, the first electrode comprising at least one layer of graphene, a second electrode, and a layer of piezoelectric material disposed between the first electrode and the second electrode, such as to cause the piezoelectric material to resonate at a resonant frequency; and
changing a bias voltage applied to the apparatus.
